(19) United States
(12) Patent Application Publication
(10) Pub. No.: US 2008/0217767 A1
(43) Pub. Date: Sep. 11, 2008

(54) Stacked-Chip Semiconductor Device

(76) Inventor: Masamoto Tago, Tokyo (JP)

Correspondence Address: HAYES SOLOWAY P.C., 3450 E. SUNRISE DRIVE, SUITE 140, TUCSON, AZ, 85718, US

(21) Appl. No.: 10/599,235

(22) PCT Filed: Mar. 25, 2005
(86) PCT No.: PCT/JP05/05544

§ 371 Date: Sep. 22, 2006

(30) Foreign Application Priority Data
Mar. 25, 2004 (JP) 2004-089199

(51) Int. Cl. H01L 23/50

(52) U.S. Cl. 257/737; 257/E23.069

(57) ABSTRACT

A chip stacking semiconductor device which can be used without mounting a converter circuit and without altering the circuitry of the semiconductor chips even when semiconductor chips stacked in a plurality of stages are connected electrically. Through wiring (5) provided in the semiconductor chip (4) is supplied with power and the ground from thick film wiring through a bump (3). Power and the ground can thereby be supplied through a short passage to a desired position of the semiconductor chip (4) located above, and a problem that the wiring resistance increases because rewiring is not required is eliminated. Consequently, operational stability of the semiconductor device is enhanced.

### TECHNICAL FIELD

The present invention relates to a semiconductor device, and more particularly relates to a stacked-chip semiconductor device.

### BACKGROUND ART

In a stacked-ship semiconductor device, there is a need to make the device thinner and more lightweight, and mounting a plurality of chips in a single package has become an important aspect. To achieve this object, a package has been developed in which the structure has a chip that is ordinarily mounted face up on the circuit surface of another chip, and the chip is connected to the lead frame and interposer substrate by wire bonding.

Methods for increasing the memory capacity in a conventional stacked-chip semiconductor device include a wiring and stacking method in which a chip is stacked face up and the chips are connected by wire bonding to an interposer substrate, and a chip-on-chip method in which chips that require high-speed signal transfer between chips are mounted face down.

Assembly of a wired and stacked semiconductor device is relatively inexpensive because the interposer substrate and the chips are connected by wires. For this reason, this method is suitably used for the purpose of increasing mounting density at relatively low cost. The method is also advantageous in that the stacked chips are each connected to an interposer substrate, and individual voltages can therefore be supplied by wires when chips with different power voltages are used.

FIG. 9 is a cross-sectional view of a conventional wired and stacked semiconductor device. A chip 2 positioned on the bottom is electrically connected to an interposer substrate 1 by way of bonding wires 2b, and power supply voltage and ground are fed from the interposer substrate 1 by way of the bonding wires 2b. Electrical signals that are input to the semiconductor chip 2 and electrical signals that are output from the semiconductor chip 2 are also transmitted between the interposer substrate 1 via bonding wires 2b. An upwardly positioned semiconductor chip 4 is electrically connected with the interposer substrate 1 by way of bonding wires 4b, and power supply voltage and ground are fed from the interposer substrate 1 via the bonding wires 4b. Electrical signals that are input to the semiconductor chip 4 and electrical signals that are output from the semiconductor chip 4 are also transmitted between the interposer substrate 1 via the bonding wires 4b.

However, with a wired and stacked package, each of the stacked chips must be connected to the interposer substrate or the lead frame. When a chip is connected to the interposer substrate, wires must be brought out of the interposer substrate, and when a chip is connected to the lead frame, wires must be brought out of the motherboard. For this reason, there is a drawback in that the interposer substrate and motherboard is more expensive because the wiring is made more complicated.

In the connection of the power supply voltage and ground, the resistance is low and stable because a bonding wire having a diameter of 20 to 30 μm is ordinarily used, but there is a problem in that parasitic capacitance increases in the signal line due to the connection, and the transmission speed is reduced. There is furthermore a problem in that high-density mounting is difficult to achieve due to the problem of the wiring density of the interposer substrate.

On the other hand, in a chip-on-chip semiconductor device, since connections are made by way of bumps used in connections between chips, there are advantages and other positive aspects (see Patent Documents 1 to 4, for example) in that the package thickness can be reduced because the transmission distance is short, high transmission speed is made possible, and there are no restrictions in the height of wire loops.

FIG. 10 is a cross-sectional view of a conventional chip-on-chip semiconductor device. Bumps 3 are disposed between the upper semiconductor chip 2 and the lower semiconductor chip 4, and the bumps electrically connect the two chips. The power supply voltage, ground, and electrical signals are fed to the semiconductor chips 2 and 4 by way of the bonding wires 2b.

[Patent Document 1] Japanese Laid-open Patent Application No. 2002-261232

[Patent Document 2] Japanese Laid-open Patent Application No. 2002-305282

[Patent Document 3] Japanese Laid-open Patent Application No. 2003-110084

[Patent Document 4] Japanese Laid-open Patent Application No. 2003-249622

### DISCLOSURE OF THE INVENTION

Problems that the Invention is to Solve

However, in a chip-on-chip package, the upper semiconductor chip is connected to a semiconductor chip that is facing downward and is positioned below, and the signal lines including power supply voltage and ground are all connected to the lower semiconductor chip. Therefore, considering the reduced voltage and other factors brought about by wire resistance, the lower semiconductor chip must be rewired in order to connect the upper semiconductor chip. In ordinary rewiring, wiring resistance increases and other problems arise, and a stable power feed cannot be fed to the semiconductor device. Another problem is that when a chip with different power voltage is mounted and connected to the lower chip, a converter must be added to the lower chip and other design modifications must be made. As a result, costs increase and the multiplicity of use of the chips is reduced.

An object of the present invention is to provide a stacked-chip semiconductor device that has good operational stability, that does not require the circuit configuration of the semiconductor chip to be changed, and that can be used without mounting a converter circuit when a plurality of tiers of semiconductor chips are electrically connected to each other in a chip-on-chip semiconductor device.

### Means of Solving the Problems

The stacked-chip semiconductor device according to a first aspect of the present invention comprises an interposer substrate, and two or more semiconductor chips overlaid two tiers deep or more and mounted on the interposer substrate. At least one of the semiconductor chips has a plurality of through-wires, and at least one voltage selected from power supply voltage and ground is fed from the interposer substrate via the through-wires to one or more semiconductor chips selected from the two or more semiconductor chips.

The stacked-chip semiconductor device according to a second aspect of the present invention comprises an interposer substrate, a first semiconductor chip disposed above the interposer substrate and provided with a thick-film wiring and a circuit surface on an upper surface, a second semiconductor chip disposed above the first semiconductor chip and provided with a plurality of through-wires and a circuit surface on an upper surface; a plurality of bumps for providing an electrical connection between the through-wires and the thick-film wiring; and bonding wires for electrically connecting the interposer substrate and the thick-film wiring. At least one voltage selected from power supply voltage and ground is fed by the interposer substrate to the circuit surface of the second semiconductor chip by way of the bonding wires, the thick-film wiring, the bumps, and the through-wires.

The stacked-chip semiconductor device according to a third aspect of the present invention comprises an interposer substrate, a first semiconductor chip that is disposed above the interposer substrate and that has a thick-film wiring and a circuit surface on an upper surface, a second semiconductor chip that is disposed above the first semiconductor chip and that has a plurality of through-wires and a circuit surface on a lower surface, a plurality of bumps for providing an electrical connection between the second semiconductor chip and the thick-film wiring, and bonding wires for electrically connecting the interposer substrate and the thick-film wiring. Power supply voltage and ground are fed from the interposer substrate to the circuit surface of the second semiconductor chip by way of the bonding wire, the thick-film wiring, and the bumps; and electrical signals are transmitted between the interposer substrate and the circuit surface of the second semiconductor chip by way of the through-wires and the bonding wires.

The thickness of the thick-film wiring is preferably the same as the height of the bumps. The thick-film wiring and the bumps may be formed by plating.

The stacked-chip semiconductor device according to a fourth aspect of the present invention comprises an interposer substrate, a first semiconductor chip that is disposed above the interposer substrate and that has a plurality of through-wires, a second semiconductor chip that is disposed above the first semiconductor chip and that has a circuit surface on a lower surface, a plurality of first bumps for electrically connecting the through-wires and the interposer substrate, and a plurality of second bumps for electrically connecting the through-wires and the second semiconductor chip. At least one voltage selected from power supply voltage and ground is fed from the interposer substrate to the circuit surface of the second semiconductor chip by way of the first bumps, the through-wires, and the second bumps.

The stacked-chip semiconductor device according to a fifth aspect of the present invention comprises an interposer substrate, a first semiconductor chip that is disposed above the interposer substrate and that has a circuit surface on an upper surface and a thick-film wiring, a spacer that is disposed above the first semiconductor chip and that has a plurality of through-wires, a second semiconductor chip that is disposed above the spacer and that has a circuit surface on a lower surface, a plurality of first bumps for electrically connecting the through-wires and the thick-film wiring, a plurality of second bumps for electrically connecting the through-wires and the second semiconductor chip, and bonding wires for electrically connecting the interposer substrate and the thick-film wiring. At least one voltage selected from power supply voltage and ground is fed from the interposer substrate to the circuit surface of the second semiconductor chip by way of the bonding wires, the thick-film wiring, the first bumps, the through-wires, and the second bumps.

The stacked-chip semiconductor device according to a sixth aspect of the present invention comprises an interposer substrate, a first semiconductor chip that is disposed above the interposer substrate and that has a plurality of first through-wires, a spacer that is disposed above the first semiconductor chip and that has a plurality of second through-wires, a second semiconductor chip that is disposed above the spacer and that has a circuit surface on a lower surface, a plurality of first bumps for electrically connecting the interposer substrate and the first through-wires, a plurality of second bumps for electrically connecting the first through-wires and the second through-wires, and a plurality of third bumps for electrically connecting the second through-wires and second semiconductor chip. At least one voltage selected from power supply voltage and ground is fed from the interposer substrate to the circuit surface of the second semiconductor chip by way of the first bumps, the first through-wires, the second bumps, the second through-wires, and the third bumps.

The stacked-chip semiconductor device according to a seventh aspect of the present invention comprises an interposer substrate, a first semiconductor chip that is disposed above the interposer substrate and that has a circuit surface on an upper surface and thick-film wiring, a second semiconductor chip that is disposed above the first semiconductor chip and that has a plurality of through-wires, a third semiconductor chip that is disposed above the second semiconductor chip and that has a circuit surface on a lower surface, a plurality of first bumps for electrically connecting the through-wires and the thick-film wiring, a plurality of second bumps for electrically connecting the through-wires and the second semiconductor chip 2, and bonding wires for electrically connecting the interposer substrate and the thick-film wiring. At least one voltage selected from power supply voltage and ground is fed from the interposer substrate to the circuit surface of the third semiconductor chip by way of the bonding wires, the thick-film wiring, the first bumps, the through-wires, and the second bumps.

Preferably, a plurality of wires for each of the semiconductor chips for feeding the power supply voltage and ground are disposed in parallel for each of the semiconductor chips, and are each connected in parallel to a single wire within the interposer substrate, semiconductor chip, or spacer.

### Effects of the Invention

In the present invention, at least one voltage selected from power supply voltage and ground is fed using through-wires in the semiconductor chips stacked in a plurality of tiers. Therefore, power voltage can be fed via a short pathway to the individual circuits on the semiconductor chips. For this reason, the circuit configuration of the semiconductor chips does not need to be changed, the semiconductor chips can be used without a converter circuit being mounted, and a semiconductor device with excellent operation stability can be provided because voltage reduction and other factors caused by wiring resistance do not need to be considered when the semiconductor chips stacked in a plurality of tiers are electrically connected. The effects are the same for a case in which signals are transmitted by way of through-wires.

### BRIEF DESCRIPTION OF THE DRAWINGS

FIG. 1 is a cross-sectional view of the stacked-chip semiconductor device according to the first embodiment of the present invention;

FIG. 2 is a cross-sectional view of the stacked-chip semiconductor device according to the second embodiment of the present invention;

FIG. 3 is a cross-sectional view of the stacked-chip semiconductor device according to the third embodiment of the present invention;

FIG. 4 is a cross-sectional view of the stacked-chip semiconductor device according to the fourth embodiment of the present invention;

FIG. 5 is a cross-sectional view of the stacked-chip semiconductor device according to the fifth embodiment of the present invention;

FIG. 6 is a cross-sectional view of the stacked-chip semiconductor device according to the sixth embodiment of the present invention;

FIG. 7 is a cross-sectional view of the stacked-chip semiconductor device according to the seventh embodiment of the present invention;

FIG. 8 is a diagram showing an embodiment of the bumps 3 and thick-film wiring 2c;

FIG. 9 is a cross-sectional view of a conventional wired and stacked semiconductor device; and

FIG. 10 is a cross-sectional view of a conventional chip-on-chip semiconductor device.

### DESCRIPTION OF THE REFERENCE NUMERALS

1: interposer substrate
2, 4: semiconductor chips
2a, 4a: circuit surfaces
2b, 4b: bonding wires
3: bump
5: through-wires
6: solder ball
7: spacer

### BEST MODE FOR CARRYING OUT THE INVENTION

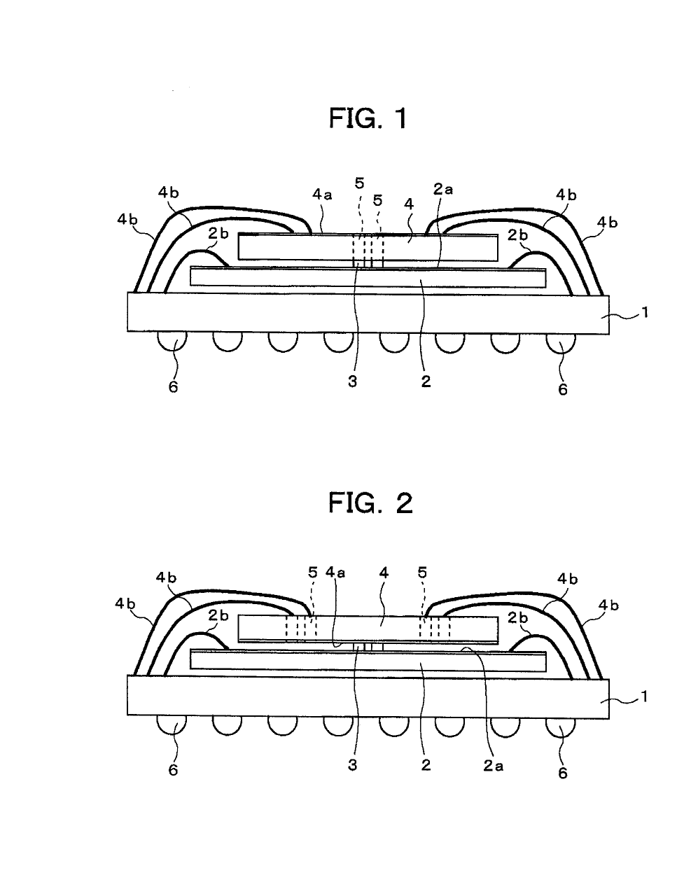

Embodiments of the present invention are described in detail below with reference to the attached diagrams. FIG. 1 is a cross-sectional view of a stacked-chip semiconductor device according to the first embodiment of the present invention. A semiconductor chip 2 is mounted on the interposer substrate 1. The circuit surface 2a and the thick-film wiring 2c (see FIG. 8) are formed on the upper surface of the semiconductor chip 2. A semiconductor chip 4 having a plurality of through-wires 5 is disposed on the semiconductor chip 2. The lower portion of each of a plurality of through-wires 5 is connected to the thick-film wiring 2c of the semiconductor chip 2 by way of bumps 3, and the upper portions of the through-wires 5 are connected to the circuit surface 4a formed on the upper surface of the semiconductor chip 4. The semiconductor chip 2 and semiconductor chip 4 are connected by way of the bumps 3. The thick-film wiring 2c formed on the upper surface of the semiconductor chip 2 is connected to the interposer substrate 1 by way of bonding wires 2b. The circuit surface 4a formed on the upper surface of semiconductor chip 4 is connected to the interposer substrate 1 by way of bonding wires 4b. The entire configuration is sealed with resin and is then packaged. Solder balls 6 bond the interposer substrate 1 to another board, and also connect the wiring within the interposer substrate 1 to the wiring of another board.

Described next is the operation of the stacked-chip semiconductor device according to the first embodiment of the present invention. Power supply voltage and ground are fed to the thick-film wiring 2c formed on the upper surface of the semiconductor chip 2 via the bonding wires 2b. The power supply voltage and ground fed to the thick-film wiring 2c are provided to circuits in the circuit surface 2b on the semiconductor chip 2. The power supply voltage and ground fed to the thick-film wiring 2c are fed to the circuit surface 4a formed on the upper surface of the semiconductor chip 4 via the thick-film wiring 2c, bumps 3, and through-wires 5. The electrical signals input to the circuit surface 2a on the semiconductor chip 2, and the electrical signals output from the circuit surface 2a on the semiconductor chip 2, are transmitted to and from the interposer substrate 1 by way of the bonding wires 2b. The electrical signals input to the circuit surface 4a on the semiconductor chip 4, and the electrical signals output from the circuit surface 4a on the semiconductor chip 4, are transmitted to and from the interposer substrate 1 by way of the bonding wires 4b.

Described next are the effects of the stacked-chip semiconductor device according to the first embodiment of the present invention. In the present embodiment, electrical signals are transmitted between the semiconductor chips 2 and 4 and the interposer substrate 1 through bonding wires 2b and 4b, respectively. A power supply voltage and ground are fed from the thick-film wiring 2c to the through-wires 5 provided to the upper semiconductor chip 4 via the bumps 3. Therefore, the power supply voltage and ground can be fed via a short pathway to desired locations of the upper semiconductor chip 4, and since rewiring is no longer required, there is no problem in which the wiring resistance increases. For this reason, the operational stability of the semiconductor device is increased. Power supply voltage and ground are conventionally fed from the semiconductor chip 2 to the semiconductor chip 4 by way of bonding wires or bumps, and there was therefore a need to rewire the chips considering the lower voltage and other factors caused by wire resistance within the chips.

The second embodiment of the present invention is described next. In the second embodiment, the same reference numerals are used for the same constituent elements as those in the first embodiment, and a description of these elements is omitted.

FIG. 2 is a cross-sectional view of the stacked-chip semiconductor device according to the second embodiment of the present invention. The stacked-chip semiconductor device according to the second embodiment is different from the configuration of the first embodiment in that the upper semiconductor chip 4 is stacked face down. The circuit surface 4a of the upper semiconductor chip 4 is connected by way of bumps 3 to the circuit surface 2a of the lower semiconductor chip 2. Also, the circuit surface 4a is connected to the interposer substrate 1 by way of through-wires 5 and bonding wires 4c. The entire structure is sealed with resin and is then packaged. Solder balls 6 bond the interposer substrate 1 to another board, and also connect the wiring within the interposer substrate 1 to the wiring of other boards.

The operation of the second embodiment of the present invention is described next. Power supply voltage and ground fed to the circuit surface 4a of the semiconductor chip 4 are fed from the interposer substrate 1 by way of the bonding wires 2b, thick-film wiring 2c, and bumps 3. The electrical signals input to the circuit surface 4a on the semiconductor chip 4, and the electrical signals output from the circuit surface 4a on the semiconductor chip 4, are transmitted to and from the interposer substrate 1 by way of the through-wires 5 and the bonding wires 4b. The electrical signals input to the circuit surface 4a on the semiconductor chip 4, and the electrical signals output from the circuit surface 4a on the semiconductor chip 4, are transmitted to and from the interposer substrate 1 by way of the bonding wires 4b.

The effects of the second embodiment of the present invention are the same as those in the first embodiment.

The third embodiment of the present invention is described next. In the third embodiment, the same reference numerals are used for the same constituent elements as those in the first and second embodiments, and a description of these elements is omitted.

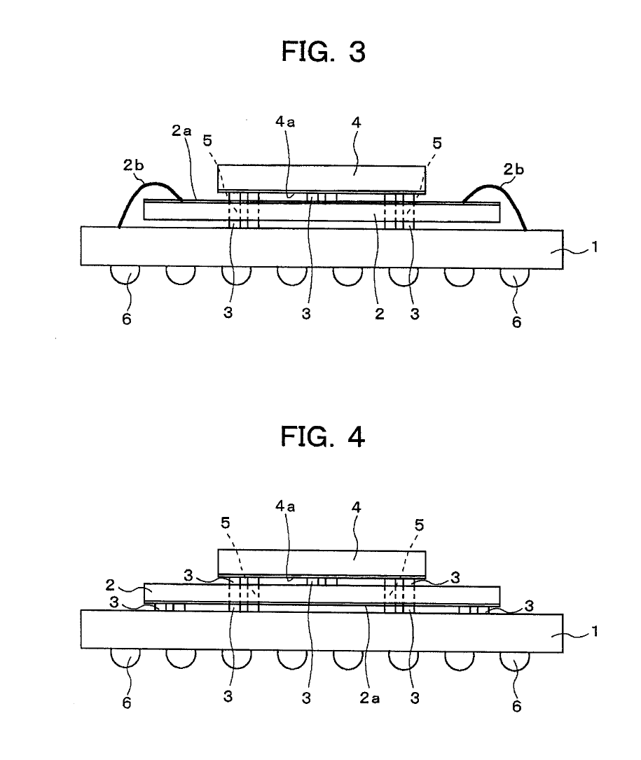

FIG. 3 is a cross-sectional view of the stacked-chip semiconductor device according to the third embodiment of the present invention. The stacked-chip semiconductor device according to the third embodiment is different from the configuration of the first and second embodiments in that through-wires 5 are disposed in the lower semiconductor chip 2 and that bonding wires are not used to connect the interposer substrate 1 and the semiconductor chip 4. The lower portions of the through-wires 5 disposed in the semiconductor chip 2 are connected to the interposer substrate 1 by way of bumps 3, and the upper portions are connected by way bumps 3 to the upper semiconductor chip 4. The entire structure is sealed with resin and is then packaged. Solder balls 6 bond the interposer substrate 1 to other boards, and also connect the wiring within the interposer substrate 1 to the wiring of other boards.

Described next is the operation of the stacked-chip semiconductor device according to the third embodiment of the present invention. The power supply voltage and ground of the semiconductor chip 2 are fed to the thick-film wiring 2c by way of bonding wires 2b. The power supply voltage and ground fed to the thick-film wiring 2c are fed to the circuits in the circuit surface 2a on the semiconductor chip 2. The power supply voltage and ground of the semiconductor chip 4 are fed from the interposer substrate 1 by way of the through-wires 5 and the bumps 3 disposed above and below the through-wires. The electrical signals input to the semiconductor chip 2 and the electrical signals output from the semiconductor chip 2 are transmitted to and from the interposer substrate 1 by way of the bonding wires 2c. The electrical signals input to the semiconductor chip 4 and the electrical signals output from the semiconductor chip 4 are transmitted to and from the interposer substrate 1 by way of the bonding wires 2c, thick-film wiring 2a, and the bumps 3. The electrical signals may alternatively be transmitted to and from the interposer substrate 1 by way of the through-wires 5 of the semiconductor chip 2 and the bumps 3 disposed above and below the through-wires.

Described next are the effects of the stacked-chip semiconductor device according to the third embodiment of the present invention. In the present embodiment, the operational stability of the semiconductor device is improved because the power supply voltage and ground of the semiconductor chip 4 are fed from the interposer substrate 1 by way of the through-wires 5 and the bumps 3 arranged above and below the through-wires. The power supply voltage and ground fed to the semiconductor chip 2 are differentiated and fed via a short pathway. Also, the circuits do not require reconfiguration even if the semiconductor chip 4 is stacked on the semiconductor chip 2. This is because the power supply voltage and ground are directly fed from the interposer substrate 1 by way of the through-wires 5 and the bumps 3 arranged above and below the through-wires in required locations of the semiconductor chip 4 disposed above. Furthermore, the operating voltages of the semiconductor chip 4 and semiconductor chip 2 are often different when different functions are combined to form a system-in-package, or in other situations. However, even if the operating voltages of the two are different, a converter does not need to be added to the lower chip. This is because power supply voltage and ground are fed to the circuit formed on the surface of the upper semiconductor chip 4 via pathways that are separate from the operating power source of the semiconductor chip 2, i.e., the pathways that are fed from the interposer substrate 1 via the through-wires 5 and the bumps 3 disposed above and below the through-wires. Since the exchange of electrical signals between the semiconductor chips 2 and 4 is moreover carried out by way of the bumps 3, there is also an effect whereby the output speed of the semiconductor device is increased.

The fourth embodiment of the present invention is described next. In the fourth embodiment, the same reference numerals are used for the same constituent elements as those in the third embodiment, and a description of these elements is omitted.

FIG. 4 is a cross-sectional view of the stacked-chip semiconductor device according to the fourth embodiment of the present invention. The stacked-chip semiconductor device according to the fourth embodiment is different from the configuration of the third embodiment in that bonding wires are not used to connect the interposer substrate 1 and the semiconductor chip 2. In lieu of the absent bonding wires, bumps 3 are disposed under the through-wires 5 and also in other locations between the semiconductor chip 2 and interposer substrate 1. The entire configuration is sealed with resin and is then packaged. Solder balls 6 bond the interposer substrate 1 to another board, and also connect the wiring within the interposer substrate 1 to the wiring of another board.

Described next is the operation of the stacked-chip semiconductor device according to the fourth embodiment of the present invention. The power supply voltage and ground of the semiconductor chip 2 are fed by way of bumps 3 between the interposer substrate 1 and semiconductor chip 2 disposed in locations other than below the through-wires 5. The power supply voltage and ground of the semiconductor chip 4 are fed from the interposer substrate 1 by way of the through-wires 5 and the bumps 3 arranged above and below the through-wires, in the same manner as the third embodiment. The electrical signals input to the semiconductor chip 2 and the electrical signals output from the semiconductor chip 2 are transmitted to and from the interposer substrate 1 by way of the bumps 3 between the interposer substrate 1 and semiconductor chip 2 disposed in locations other than below the through-wires 5. The electrical signals input to the semiconductor chip 4 and the electrical signals output from the semiconductor chip 4 are transmitted to and from the interposer substrate 1 by way of the through-wires 5 and the bumps 3 arranged above and below the through-wires.

Described next are the effects of the stacked-chip semiconductor device according to the fourth embodiment of the present invention. In the present embodiment, the power supply voltage and ground of the semiconductor chip 4 are fed from the interposer substrate 1 by way of the through-wires 5 of the semiconductor chip 2 and the bumps 3 arranged above and below the through-wires, and are different from the pathways provided to the semiconductor chip 2. For this reason, the configuration of the circuits of the semiconductor chip 2 does not need to be modified even if a semiconductor chip 4 is stacked on the semiconductor chip 2. Also, a converter does not need to be provided to the semiconductor chip 2, even if the operating voltages of the semiconductor chip 2 and semiconductor chip 4 are different. The operating power supply of the semiconductor chips 2 and 4 can therefore be stably supplied. The bumps 3 are used to transmit electrical signals that are input to the semiconductor chip 2, and to transmit electrical signals output from the semiconductor chip 2. The through-wires 5 and the bumps 3 arranged above and below the through-wires are used to transmit electrical signals that are input to the semiconductor chip 4, and to transmit electrical signals output from the semiconductor chip 4. For this reason, the transmission distance between the chips above and below is shortened, and the speed of the signal transmission can be increased. Since the exchange of electrical signals between the semiconductor chips 2 and 4 is furthermore carried out by way of the bumps 3, there is also an effect whereby the output speed of the semiconductor device is increased. Also, the entire semiconductor device can be made smaller because bonding wires are not used.

The fifth embodiment of the present invention is described next. In the fifth embodiment, the same reference numerals are used for the same constituent elements as those in the first to fourth embodiments, and a description of these elements is omitted.

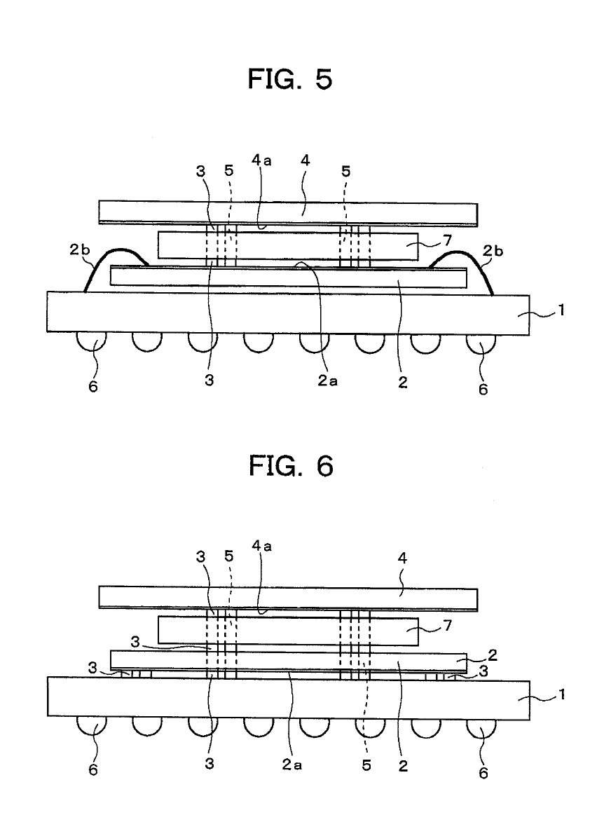

FIG. 5 is a cross-sectional view of the stacked-chip semiconductor device according to the fifth embodiment of the present invention. The stacked-chip semiconductor device according to the fifth embodiment is different from the first to fourth embodiments in that a spacer 7 having through-wires 5 is inserted between the semiconductor chips 2 and 4. The entire configuration is sealed with resin and is then packaged. The spacer 7 may be a material having electric insulation characteristics. Solder balls 6 bond the interposer substrate 1 to another board, and also connect the wiring within the interposer substrate 1 to the wiring of another board.

Described next is the operation of the stacked-chip semiconductor device according to the fifth embodiment of the present invention. The power supply voltage and ground are fed by way of bonding wires 2c to the thick-film wiring 2a formed on the upper surface of the semiconductor chip 2. The power supply voltage and ground fed to the thick-film wiring 2a are fed to the circuit on the circuit surface 2b on the semiconductor chip 2. Also, power supply voltage and ground are fed, by way of the thick-film wiring 2a, the bumps 3 formed above and below the through-wires 5, and the through-wires 5, to the circuit surface 4a formed on the lower surface of the semiconductor chip 4. The electrical signals input to the circuit surface 2a on the semiconductor chip 2, and the electrical signals output from the circuit surface 2a on the semiconductor chip 2, are transmitted to and from the interposer substrate 1 by way of the bonding wires 2b. The electrical signals input to the circuit surface 4a on the semiconductor chip 4, and the electrical signals output from the circuit surface 4a on the semiconductor chip 4, are transmitted to and from the interposer substrate 1 by way of bumps 3 disposed above and below the through-wires 5, the through-wires 5, the thick-film wiring 2a, and the bonding wires 2c.

Described next are the effects of the stacked-chip semiconductor device according to the fifth embodiment of the present invention. In the present embodiment, since a spacer 7 having through-wires 5 is inserted between the semiconductor chips 2 and 4, there is no need to limit the size of the semiconductor chip 4 disposed above. Bonding wires 2b for forming a connection between the semiconductor chip 2 and the interposer substrate can be provided even if the semiconductor chip 4 is larger than the semiconductor chip 2 because the spacer 7 assures a gap between the semiconductor chip 2 and semiconductor chip 4. Also, the power supply voltage and ground are fed to the semiconductor chip 4 by way of the bonding wires 2b, thick-film wiring 2c, bumps 3 disposed above and below the through-wires 5, and through-wires 5. Therefore, the power supply voltage and ground can be fed to desired locations of the upper semiconductor chip 4 by way of a short pathway, and the problem in which wiring resistance increases due to rewiring does not occur because rewiring is not required. For this reason, the operating stability of the semiconductor device is increased. Since the exchange of electrical signals between the semiconductor chips 2 and 4 is moreover carried out by way of the through-wires 5 and the bumps 3 disposed above and below the through-wires 5, there is also an effect whereby the output speed of the semiconductor device is increased.

The sixth embodiment of the present invention is described next. In the sixth embodiment, the same reference numerals are used for the same constituent elements as those in the fifth embodiment, and a description of these elements is omitted.

FIG. 6 is a cross-sectional view of the stacked-chip semiconductor device according to the sixth embodiment of the present invention. The stacked-chip semiconductor device according to the sixth embodiment is different from the fifth embodiment in that through-wires 5 and bumps 3 disposed below the through-wires are provided to the semiconductor chip 2, and the bonding wires 2c are eliminated. The entire configuration is sealed with resin and is then packaged. Solder balls 6 bond the interposer substrate 1 to another board, and also connect the wiring within the interposer substrate 1 to the wiring of another board.

Described next is the operation of the stacked-chip semiconductor device according to the sixth embodiment of the present invention. The power supply voltage and ground of the semiconductor chip 2 are fed by way of bumps 3 between the interposer substrate 1 and semiconductor chip 2 disposed in locations other than below the through-wires 5. The power supply voltage and ground of the semiconductor chip 4 are fed from the interposer substrate 1 by way of the through-wires 5 of semiconductor chip 2, the through-wires 5 of the spacer 7, and the bumps 3 arranged above and below the through-wires. The electrical signals input to the semiconductor chip 2 and the electrical signals output from the semiconductor chip 2 are transmitted to and from the interposer substrate 1 by way of the bumps 3 between the interposer substrate 1 and semiconductor chip 2 disposed in locations other than below the through-wires 5. The electrical signals input to the semiconductor chip 4 and the electrical signals output from the semiconductor chip 4 are transmitted to and from the interposer substrate 1 by way of the through-wires 5 of semiconductor chip 2, the through-wires 5 of the spacer 7, and the bumps 3 arranged above and below the through-wires.

Described next are the effects of the stacked-chip semiconductor device according to the sixth embodiment of the present invention. In the present embodiment, the power supply voltage and ground of the semiconductor chip 4 are fed from the interposer substrate 1 by way of the through-wires 5 of the semiconductor chip 2, the through-wires 5 of the spacer 7, and the bumps 3 arranged above and below the through-wires, and are different from the pathways provided to the semiconductor chip 2. For this reason, the configuration of the circuits of the semiconductor chip 2 does not need to be modified even if a semiconductor chip 4 is stacked on the semiconductor chip 2. Also, a converter does not need to be provided to the semiconductor chip 2 even if the operating voltages of the semiconductor chip 2 and semiconductor chip 4 are different. The operating power supply of the semiconductor chips 2 and 4 can therefore be stably supplied. The bumps 3 are used to transmit electrical signals that are input to the semiconductor chip 2, and to transmit electrical signals that are output from the semiconductor chip 2. The through-wires 5 of the semiconductor chip 2, the through-wires 5 of the spacer 7, and the bumps 3 arranged above and below the through-wires are used to transmit electrical signals that are input to the semiconductor chip 4, and to transmit electrical signals that are output from the semiconductor chip 4. For this reason, the transmission distance between the chips above and below can be shortened, and the speed of the signal transmission can be increased. Since the exchange of electrical signals between the semiconductor chips 2 and 4 is furthermore carried out by way of through-wires 5 of the semiconductor chip 2, the through-wires 5 of the spacer 7, and the bumps 3 arranged above and below the through-wires, there is also an effect whereby the output speed of the semiconductor device is increased. Also, the entire semiconductor device can be made smaller because bonding wires are not used.

The seventh embodiment of the present invention is described next. In the seventh embodiment, the same reference numerals are used for the same constituent elements as those in the first to sixth embodiments, and a description of these elements is omitted.

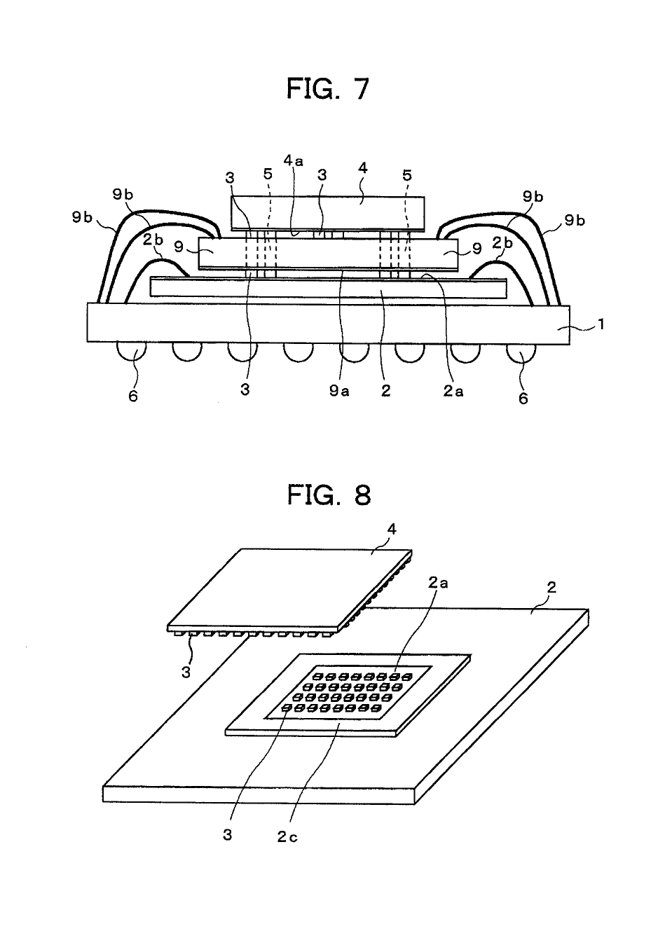

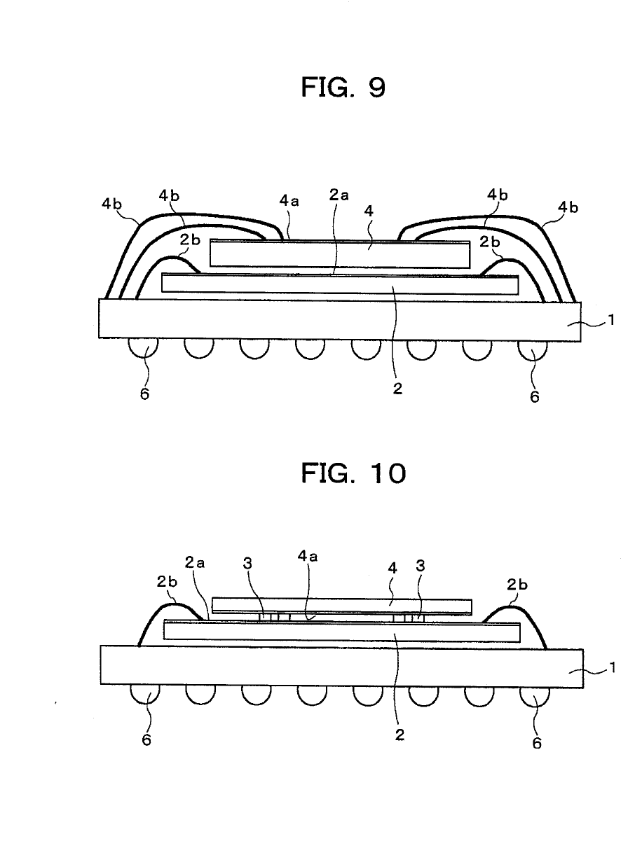

FIG. 7 is a cross-sectional view of the stacked-chip semiconductor device according to the seventh embodiment of the present invention. The stacked-chip semiconductor device according to the seventh embodiment is different from the first to sixth embodiments in that the semiconductor chip 8 having through-wires 5 is inserted between the semiconductor chips 2 and 4. The entire configuration is sealed with resin and is then packaged. Solder balls 6 bond the interposer substrate 1 to another board, and also connect the wiring within the interposer substrate 1 to the wiring of another board.

In the present embodiment, three semiconductor chips are stacked, but the operation and effects are substantially the same as when two semiconductor chips are stacked. Stacking three semiconductor chips allows numerous semiconductor chips to be stacked with high density.

Described next is an embodiment of the thick-film wiring 2c and bumps 3 for further stabilizing the power supply voltage and ground. FIG. 8 is a diagram showing an embodiment of the bumps 3 and thick-film wiring 2c. Bumps for providing connections are formed by plating on the semiconductor chip 2, and an even higher level of stable operation is made possible by forming the bumps 3 and thick-film wiring 2c at the same time. The thicknesses of the thick-film wiring 2c and bumps 3 are made equal by forming the bumps 3 and thick-film wiring 2c at the same time. Therefore, the thickness of the thick-film wiring 2c is not greater than the thickness of the bumps 3, and the thick-film wiring 2c can be made thicker in accordance with the thickness of the bumps 3. If the thickness of the thick-film wiring 2c is increased, low-resistance wiring can be achieved. If the thickness of the thick-film wiring 2c and the thickness of the bumps 3 are the same, the thick-film wiring 2c does not become an obstacle to bump 3 connections. If the thickness of the thick-film wiring 2c is considerable, the amount of electric current that can be used increases, and the thick-film wiring 2c can therefore provide a power supply voltage and ground to the wiring even if the number of wires connected to the thick-film wiring 2c increases considerably. For this reason, semiconductor chips can be stacked on a semiconductor chip without modifying the circuit of the stacked and mounted semiconductor chip or rerouting the wires within the interposer substrate, and a cost savings can be achieved.

As described above, the through-wires 5 contribute to an improvement in operational stability when the power supply voltage and ground are fed to a semiconductor chip mounted on a semiconductor chip. As noted in the effects of some of the embodiments described above, the through-wires 5 can also be used to feed electrical signals. In such a case, the through-wires can contribute to enhanced speed and other aspects of signal transmission because the connection distance between electrodes is shortened.

As described in the present invention, power supply can be fed over the shortest wiring distance to a specific circuit of an LSI chip in which an IR drop (a reduction in power voltage) can be caused by wiring drawn around within the LSI. This is because power supply voltage and ground are fed to semiconductor chips by way of through-wires. In the particular case that voltage is fed from the end portion of a chip, the voltage drop increases in the center of the chip. Through-wires are preferably disposed in the center area of the chip, and the power supply or ground is preferably connected to the through-wires in order to minimize the voltage drop to the extent possible. A plurality of power supplies and grounds are sometimes provided, but in such a case, only a portion of the power supplies and grounds may be fed via through-wires. In other words, at least one power supply voltage and ground may be connected to the through-wires. Alternatively, all of the power supplies and grounds may be fed by way of the through-wires. The ground is ordinarily fed as one of a pair with the power supply in order to assure the necessary power voltage.

Signals may be transmitted via through-wires. In other words, the through-wires may be used for signal transmission as well as power supply voltage and ground, allowing power supply voltage and ground to coexist with signal transmission.

In the embodiments described above, the package is a BGA-type (Ball Grid Array) package, but the present invention can also be similarly applied to a QFP-type (Quad Flat Package) package, and all other stacked packages.

### INDUSTRIAL APPLICABILITY

The stacked-chip semiconductor device of the present invention can be used in BGA, QFP, and other stacked packages.

1-24. (canceled)

25. A stacked-chip semiconductor device comprising:
an interposer substrate; and
a plurality of semiconductor chips overlaid two tiers deep or more and mounted on said interposer chip, wherein
at least one of said semiconductor chips has a thick-film wiring, and at least one voltage selected from power supply voltage and ground is fed from said interposer substrate by way of said thick-film wiring to a circuit surface of another semiconductor chip that is disposed above said semiconductor chip.

26. The stacked-chip semiconductor device according to claim 25, said plurality of semiconductor chips being composed of: a first semiconductor chip that has a circuit surface on an upper surface and said thick-film wiring; and a second semiconductor chip that is disposed above said first semiconductor chip and that has a plurality of through-wires and a circuit surface on an upper surface, comprising:
a plurality of bumps for providing an electrical connection between said plurality of through-wires and said thick-film wiring; and
bonding wires for electrically connecting said interposer substrate and said thick-film wiring, wherein
at least one voltage selected from power supply voltage and ground is fed from said interposer substrate to the circuit surface of said second semiconductor chip by way of said bonding wires, said thick-film wiring, said plurality of bumps, and said plurality of through-wires.

27. The stacked-chip semiconductor device according to claim 25, said plurality of semiconductor chips being composed of: a first semiconductor chip that has a circuit surface on an upper surface and said thick-film wiring; and a second semiconductor chip that is disposed above said first semiconductor chip and that has said plurality of through-wires and a circuit surface on a lower surface, comprising:
a plurality of bumps for providing an electrical connection between said second semiconductor chip and said thick-film wiring;
bonding wires for electrically connecting said interposer substrate and said thick-film wiring; and
other bonding wires for providing an electrical connection between said interposer substrate and said second semiconductor chip,
wherein a power supply voltage and ground are fed from said interposer substrate to the circuit surface of said second semiconductor chip by way of said bonding wire, said thick-film wiring, and said plurality of bumps, and
electrical signals are transmitted between the circuit surface of said second semiconductor chip and said interposer substrate by way of said plurality of through-wires and said other bonding wires.

28. The stacked-chip semiconductor device according to claim 25, wherein a spacer formed with through-wires is disposed between said semiconductor chip and said other semiconductor chip, and at least one voltage selected from power supply voltage and ground is fed from said interposer substrate by way of said thick-film wiring and said through-wire to the circuit surface of another semiconductor chip.

29. The stacked-chip semiconductor device according to claim 26, wherein the thickness of said thick-film wiring is the same as the height of said plurality of bumps.

30. The stacked-chip semiconductor device according to claim 29, wherein said thick-film wiring and said plurality of bumps are formed by plating.

31. A stacked-chip semiconductor device comprising:
an interposer substrate;
a first semiconductor chip that is disposed above said interposer substrate and that has a plurality of through-wires;
a second semiconductor chip that is disposed above said first semiconductor chip and that has a circuit surface on a lower surface;
a first conducting member that feeds at least one voltage selected from power supply voltage and ground to a circuit surface of said first semiconductor chip; and
a second conducting member that feeds at least one voltage selected from power supply voltage and ground to said circuit surface of said second semiconductor chip,
wherein said first conductive member and said second conductive member are mutually independent routes.

32. The stacked-chip semiconductor device according to claim 31, wherein the second conducting member that feeds a power supply voltage and ground to the circuit surface of said second semiconductor chip has a plurality of through-wires disposed on said first semiconductor chip, and at least one voltage selected from power supply voltage and ground is fed from said interposer substrate to the circuit surface of said second semiconductor chip by way of said plurality of through-wires.

33. The stacked-chip semiconductor device according to claim 32, wherein a spacer that has a plurality of through-wires is disposed between said first semiconductor chip and said second semiconductor chip, and at least one voltage selected from power supply voltage and ground is fed from maid interpomer substrate by way of the through-wires of said first semiconductor chip and the through-wires of said spacer to the circuit surface of second semiconductor chip.

34. The stacked-chip semiconductor device according to claim 32, wherein the first conducting member that feeds a power supply voltage and ground to the circuit surface of said first semiconductor chip has a thick-film wiring disposed on said first semiconductor chip, and at least one voltage selected from power supply voltage and ground is fed from said interposer substrate to the circuit surface of said first semiconductor chip by way of said thick-film wiring.

35. The stacked-chip semiconductor device according to claim 33, comprising:
a plurality of first bumps for electrically connecting the plurality of through-wires of said first semiconductor chip and said interposer substrate; and
a plurality of second bumps for electrically connecting the plurality of through-wires of said first semiconductor chip and said second semiconductor chip.

36. The stacked-chip semiconductor device according to claim 35, wherein said thick-film wiring of said first semiconductor chip is disposed on a lower surface of said first semiconductor chip, and the thickness of said thick-film wiring is the same as the height of said first bumps.

37. The stacked-chip semiconductor device according to claim 35, wherein said thick-film wiring of said first semiconductor chip is disposed on an upper surface of said first semiconductor chip, and the thickness of said thick-film wiring is the same as the height of said second bumps.
